(19) United States
(12) Patent Application Publication
(10) Pub. No.: US 2026/0147060 A1
(43) Pub. Date: May 28, 2026

(54) MODULAR CIRCUIT BREAKER SYSTEM AND PCBA DIFFERENTIAL SENSOR SYSTEM FOR CIRCUIT BREAKER

(71) Applicant: Schneider Electric USA, Inc., Boston, MA (US)

(72) Inventors: Collin Richard FISCHELS, Independence, IA (US); Juan Ignacio MELECIO RAMIREZ, North Liberty, IA (US)

(21) Appl. No.: 19/228,305

(22) Filed: Jun. 4, 2025

Related U.S. Application Data
(60) Provisional application No. 63/724,487, filed on Nov. 25, 2024.

(51) Int. Cl. G01R 31/52; G01R 31/327; H02H 3/16

(52) U.S. Cl. CPC G01R 31/52; G01R 31/3277; H02H 3/16

(57) ABSTRACT

A modular multifunction circuit breaker is constructed as an assembly of separate mechanical and electronics circuit breaker modules. Each module includes a respective electrical module connector, and the electrical module connectors connect when the two modules are attached so that a current path through the mechanical circuit breaker module is connected to a current sensor in the electronics module and a mechanical switching device in the mechanical circuit breaker module is actuatable by the electronics circuit breaker module. A printed circuit board assembly (PCBA) differential sensor system for use in a circuit breaker includes a PCBA substrate defining a conductor opening. The conductor opening receives a primary conductor. A current transformer (CT) core in the PCBA substrate circumscribes the conductor opening. PCBA conductors on the PCBA substrate define at least one winding around the CT core.

### CROSS-REFERENCE TO RELATED APPLICATION

This application claims priority to U.S. Provisional Patent Application 63/724,487, filed on Nov. 25, 2024, which is hereby incorporated by reference in its entirety.

### BACKGROUND

Circuit breakers are used to protect against electrical hazards. These devices use sensors to detect fault conditions (e.g., ground faults, grounded neutral events, arc faults, and overcurrent events) and subsequently interrupt current flow to a circuit to protect individuals and equipment. In the design and manufacture of circuit breakers and the sensors they rely upon, there are challenges to ensuring accuracy, reliability, and manufacturing consistency.

### SUMMARY

In one aspect, a printed circuit board assembly (PCBA) differential sensor system for use in a circuit breaker comprises a PCBA substrate defining a conductor opening. The conductor opening is configured to receive a primary conductor. A current transformer (CT) core in the PCBA substrate circumscribes the conductor opening. PCBA conductors on the PCBA substrate define at least one winding around the CT core.

In another aspect, a modular multifunction circuit breaker (MFCB) comprises a mechanical circuit breaker module comprising a first enclosure, a first electrical module connector on the first enclosure, and a mechanical switching device in the enclosure and configured to be selectively actuated to interrupt current flow between electrical distribution equipment and a load. An electronics circuit breaker module comprises a second enclosure, a second electrical module connector on the second enclosure, an electronic current sensor in the second enclosure, and a controller connected to the electronic current sensor. The electronics circuit breaker module is attachable to the mechanical circuit breaker module. When the electronics circuit breaker module is attached to the mechanical circuit breaker module, an electrical connection is made between the second electrical module connector and the first electrical module connector such that the electronic current sensor is configured to sense current flowing through the modular MFCB between the electrical distribution equipment and the load and the controller is configured, based on the sensed current, to issue trip signals configured to actuate the mechanical switching device.

In another aspect, a mechanical circuit breaker module comprises an enclosure. A mechanical switching device in the enclosure is configured to be selectively actuated to interrupt current flow between electrical distribution equipment and a load. An equipment connector is configured to connect to the electrical distribution equipment. An electrical module connector is provided. The enclosure is configured to attach to any one electronics circuit breaker module selected from a set of electronics circuit breaker modules of a plurality of different electronics circuit breaker module types whereby an electrical connection is made between the module electrical connector and a module electrical connector of the selected electronic circuit breaker module configured to connect a primary conductor of a current sensor of the electronics circuit breaker module to the electrical equipment connector.

Other aspects will be in part apparent and in part pointed out hereinafter.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is an illustration of a modular circuit breaker system;

FIG. 2 is an elevation of a modular multifunction circuit breaker (MFCB) assembled from the modular multifunction circuit breaker system of FIG. 1, wherein a mechanical circuit breaker module of the modular MFCB is separated from an electronics circuit breaker module thereof;

FIG. 3 is a perspective of the scene in FIG. 2;

FIG. 4 is another perspective of the scene in FIG. 2;

FIG. 5 is an elevation of the modular MFCB after it has been assembled;

FIG. 6 is a perspective of the modular MFCB;

FIG. 7 is an elevation of the modular MFCB with portions of an enclosure thereof removed to reveal internal components;

FIG. 8 is a perspective of the scene in FIG. 7;

FIG. 9 is an elevation of another embodiment of a multifunction circuit breaker electronics circuit breaker module configured to be assembled together with the mechanical circuit breaker module depicted in FIG. 1 to make another embodiment of a modular MFCB, wherein a portion of an enclosure of the electronics circuit breaker module in FIG. 9 has been removed to reveal internal components;

FIG. 10 is a perspective of the scene in FIG. 9;

FIG. 11 is another perspective of the scene in FIG. 9;

FIG. 12 is another perspective of the scene in FIG. 9;

FIG. 13 is still another perspective of the scene in FIG. 9;

FIG. 14 is a schematic block diagram of a printed circuit board assembly (PCBA) differential sensor system of the electronics circuit breaker module in FIGS. 9-13;

FIG. 15 is a perspective of the PCBA differential sensor system;

FIG. 16 is a cross section of the PCBA differential sensor system;

FIG. 17 is a perspective of a core and primary conductors of the PCBA differential sensor system;

FIG. 18 is a perspective of a portion of a PCBA substrate of the PCBA differential sensor system;

FIG. 19 is another perspective of the portion of the PCBA substrate from FIG. 18;

FIG. 20 is a cross section of the PCBA differential sensor system;

FIG. 20A is a cross-sectional schematic illustration of an example PCBA layup for the PCBA differential sensor system;

FIG. 21 is another perspective similar to FIG. 17 but including a PCBA conductor path diagram superimposed on the core to illustrate the path of windings of the PCBA differential sensor system;

FIG. 22A is a perspective of a test winding of the PCBA differential sensor system;

FIG. 22B is a plan view of the test winding;

FIG. 23A is a perspective view of a grounded neutral (GN) winding of the PCBA differential sensor system;

FIG. 23B is a plan view of the GN winding;

FIG. 24A is a perspective view of a sense winding of the PCBA differential sensor system;

FIG. 24B is a plan view of the sense winding;

FIGS. 25A and 25B are plan views of the test winding, GN winding, and sense winding as laid out in the PCBA differential sensor system; and

FIGS. 26A-26D are magnetic flux density isovalue contours diagrams showing the distribution of magnetic flux along the core during four different ground fault scenarios.

Corresponding parts are given corresponding reference characters throughout the drawings.

### DETAILED DESCRIPTION

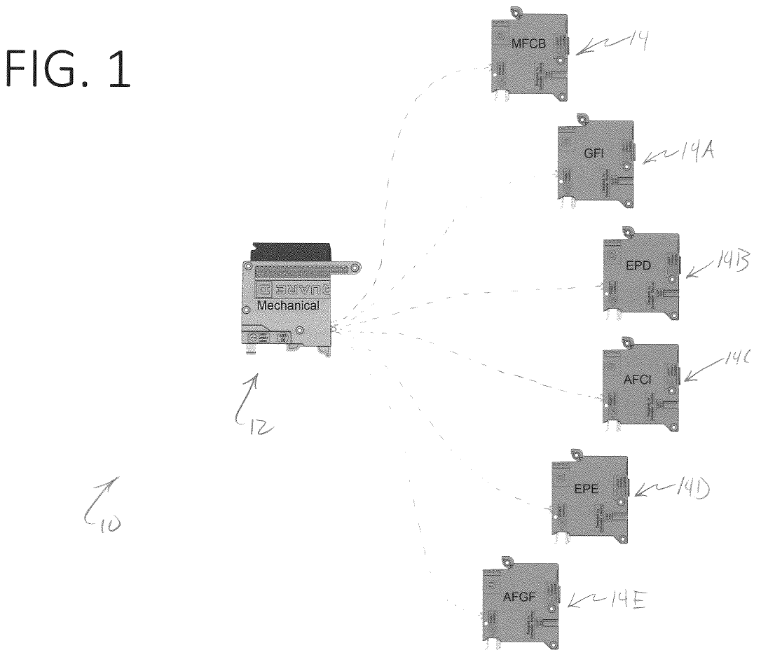

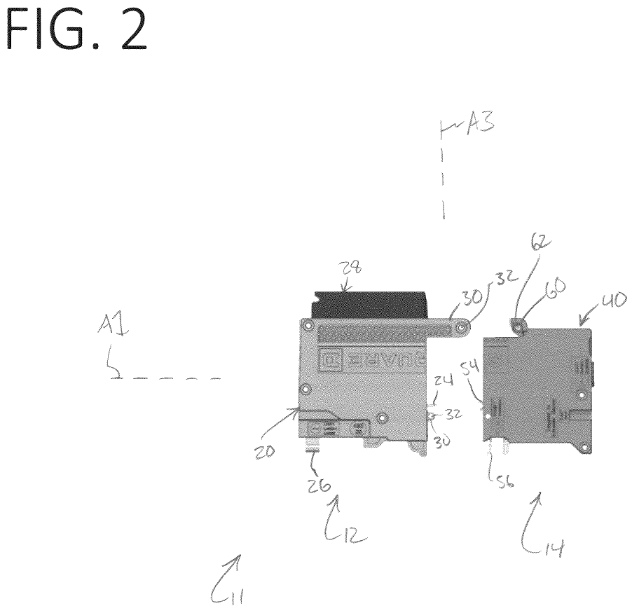

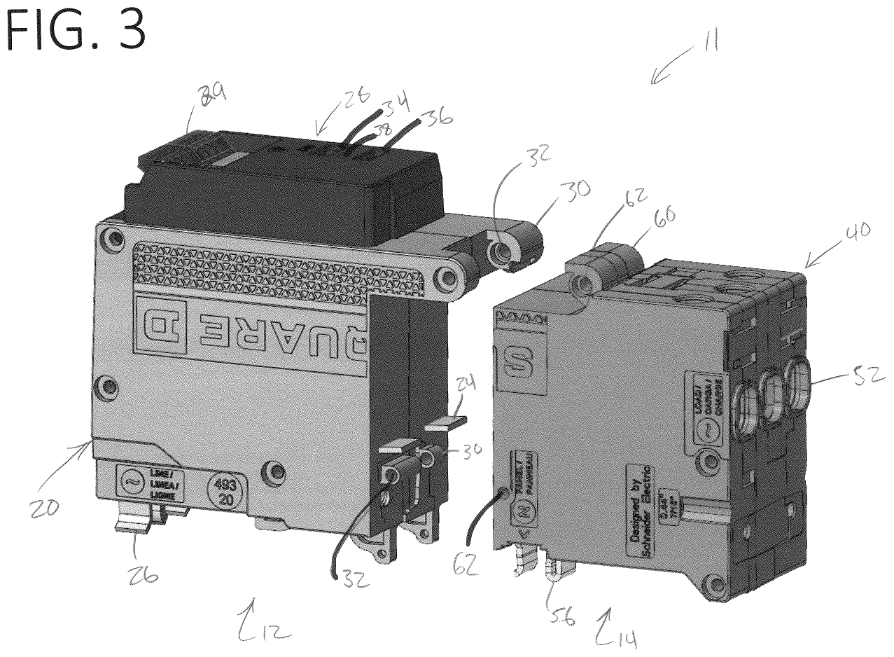

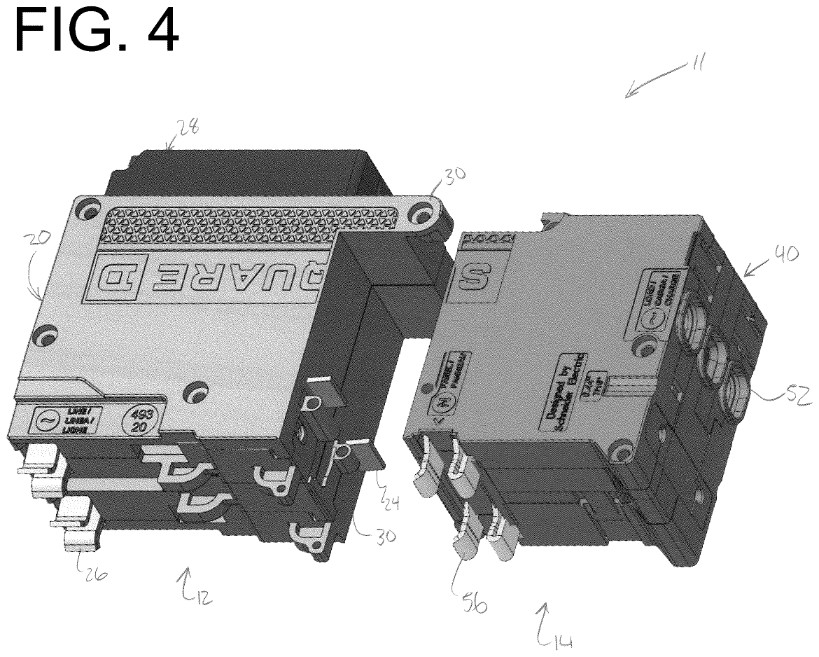

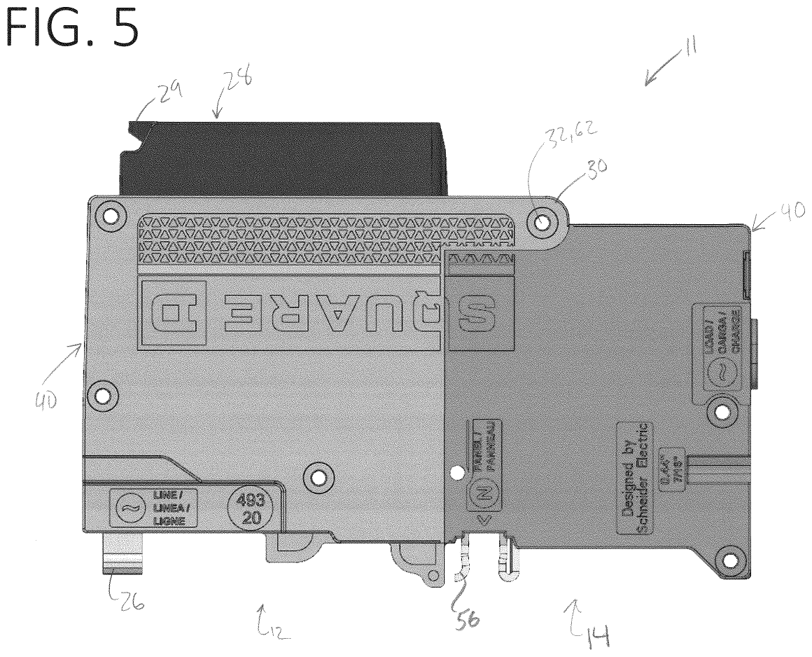

Referring to FIG. 1, a modular circuit breaker system is generally indicated at reference number 10. The modular circuit breaker system 10 broadly comprises a mechanical circuit breaker module 12 that is configured to operatively connect to any selected one of a plurality of different electronics circuit breaker modules 14, 14A, 14B, 14C, 14D, 14E to form a plurality of different types of circuit breakers. One example circuit breaker, assembled from the mechanical circuit breaker module 12 and the electronics circuit breaker module 14, is generally indicated at reference number 11 in FIGS. 2-8 and will be described in greater detail below.

Referring still to FIG. 1, in the illustrated example, the types of electronics circuit breaker modules include a multifunction electronics circuit breaker module 14, a ground fault interrupt (GFI) electronics circuit breaker module 14A, an equipment protective device (EPD) electronics circuit breaker module 14B, an arc fault circuit interrupter (AFCI) electronics circuit breaker module 14C, an equipment protective equipment (EPE) electronics circuit breaker module 14D, and an arc fault ground fault (AFGF) electronics circuit breaker module 14E. As explained more fully below, the mechanical circuit breaker module 12 broadly comprises a mechanical switching device that is configured to be selectively actuated to interrupt current flow through a circuit to which the assembled circuit breaker is connected. Each electronics circuit breaker module 14, 14A, 14B, 14C, 14D, 14E comprises an electronic current sensor (e.g., a differential current sensor) configured for detecting current flow through the circuit to which the assembled circuit breaker is connected, an electronic controller configured to selectively issue trip signals based on the signals output from the current sensors, and an actuator configured to actuate the mechanical switching device in the mechanical circuit breaker module 12 in response to the trip signals to cause the mechanical switching device to interrupt current flow through the circuit.

Accordingly, it can be seen that the modular circuit breaker system 10 provides separate, pre-assembled modules for the mechanical switching components and the electronics for various types of circuit breakers. The modular circuit breaker system 10 allows a manufacturer to use the same type of mechanical circuit breaker module 12 to provide the switching mechanism for numerous different types of circuit breakers.

Providing this type of modular platform is thought to streamline the design process for new circuit breakers. Previously, for each new circuit breaker iteration, before the new circuit breaker could be introduced to market, the entire circuit breaker was redesigned from the ground up, then a monolithic test unit was assembled, and then a complete battery of qualification testing was conducted on all aspects of the test unit. By contrast, with the modular circuit breaker system 10, the mechanical circuit breaker module 12 can be reused for each new iteration of a circuit breaker; only the electronic circuit breaker module is updated when a new circuit breaker iteration is desired.

Furthermore, prior monolithic circuit breakers were space-constrained, and it was difficult to control the locations of current paths through the unit. The uncontrolled current paths frequently caused cross-talk issues, which can impair the performance of the circuit breaker. It is believed that the modular approach of the modular circuit breaker system 10 reduces cross-talk by containing the mechanical switching components in a separate module from all electronic current sensing equipment. Separating the electronics into a dedicated module allows for precise current path routing relative to the electronic current sensors, without interference from mechanical components. This modular approach provides for substantial reduction in cross-talk issues.

Additionally, separating mechanical switching components from the electronics in two dedicated modules can provide space in the electronics module for deploying a printed circuit board (PCB) with an onboard current transformer (CT) that can achieve revenue-grade energy monitoring accuracy (±0.2%).

Referring now to FIGS. 2-8, one example embodiment of a modular multifunction circuit breaker (MFCB) is generally indicated at reference number 11. The modular MFCB 11 comprises one mechanical circuit breaker module 12 and one MFCB electronics circuit breaker module 14. As explained in further detail below, the electronics circuit breaker module 14 contains multifunction current sensing equipment and is configured to operably connect to the mechanical circuit breaker module 12 such that the electronics circuit breaker module 14 is configured to selectively actuate the mechanical circuit breaker module to interrupt current flow through a circuit.

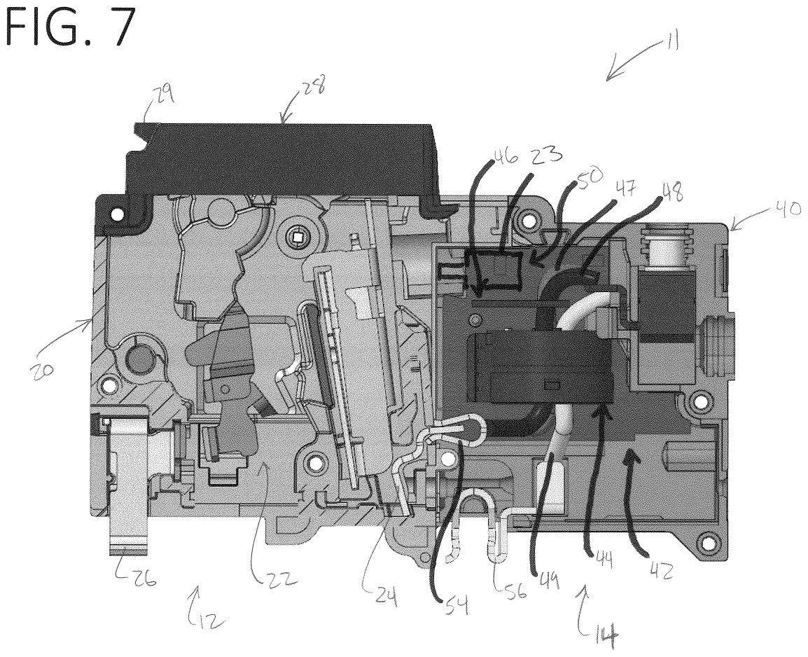

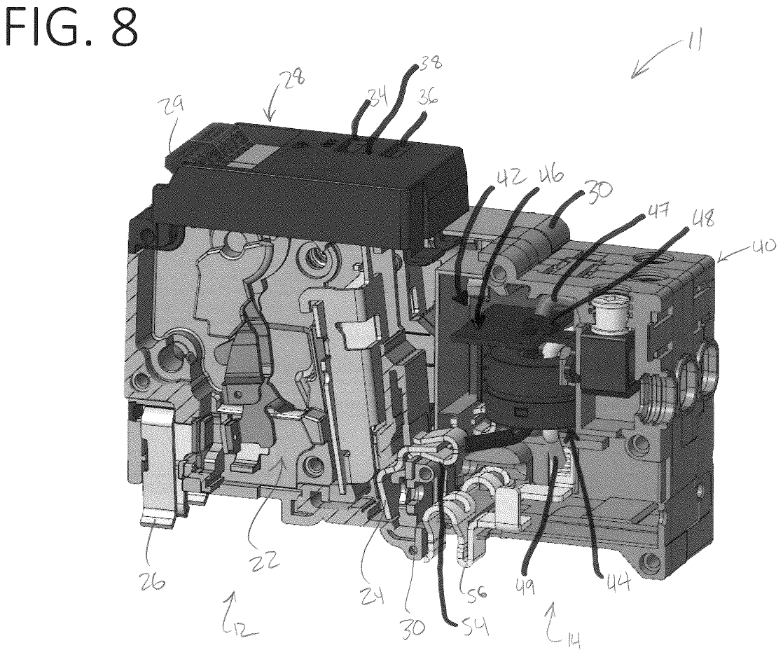

The mechanical circuit breaker module 12 comprises a first enclosure 20 configured to contain a mechanical switching device 22 (FIGS. 7-8). In one or more embodiments, the mechanical switching device 22 comprises a linkage of movable parts that are configured to normally permit current to flow through the modular MFCB 11 between an electrical distribution device, but which are also movable to interrupt current flow between the electrical distribution equipment and the load when the mechanical switching device is actuated. As shown in FIG. 7, a solenoid 23 (broadly, an actuator) is in the second enclosure 40 of the electronics circuit breaker module 14 and configured for actuating the mechanical switching device. The solenoid 23 can couple the mechanical switching device 22 magnetically, as shown, or via a mechanical link (not shown) that physically engages the mechanical switching device when the mechanical circuit breaker module 12 and the electronics circuit breaker module 14 are attached. The components and functions of a circuit breaker's mechanical switching device are well-known to those skilled in the art and will not be described further herein.

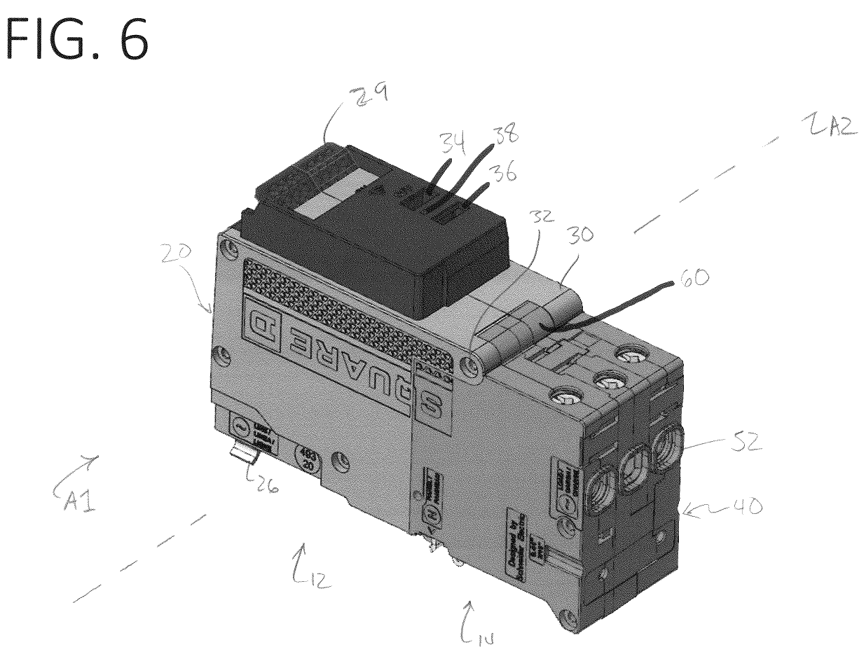

The first enclosure 20 fully contains the mechanical switching device 22 such that the mechanical switching device is physically separated from electronics contained in the electronics circuit breaker module 14 when the modular MFCB 11 is assembled. The first enclosure 20 comprises an inner end wall and an outer end wall spaced apart along a first axis A1 (FIG. 2) of the modular MFCB 11, a first broad side wall and a second broad side wall spaced apart along a second A2 (FIG. 6) of the MFCB, and an equipment side wall and a user side wall spaced apart along a third axis A3 (FIG. 2).

A first electrical module connector 24 is on (e.g., exposed on) the inner end wall of the first enclosure 20. The first electrical module connector 24 is configured to connect the mechanical switching device 22 to the electronics circuit breaker module 14 such that current can flow between the mechanical circuit breaker module 12 and the electronics circuit breaker module 14. The first electrical module connector 24 can also be used in the same way to electrically connect the mechanical circuit breaker module 12 to any of the other electronics circuit breaker modules 14A, 14B, 14C, 14D, 14E depicted in FIG. 1.

The mechanical circuit breaker module 12 further comprises an equipment connector 26 (e.g., a plug-on terminal connector) on the equipment side wall of the first enclosure 20. The equipment connector 26 is suitably configured to connect the MFCB 11 to electrical distribution equipment, in this case, specifically, a line conductor in a load center. The mechanical circuit breaker module 12 is configured to normally provide a current path from the equipment connector 26 to the first electrical module connector 24, but the mechanical switching device 22 is configured to selective disconnect the current path from the equipment connector to the first electrical module connector when actuated. During use, this interrupts the flow of current from the electrical distribution equipment through the modular MFCB 11 to a load.

At least one of the circuit breaker modules 12, 14 comprises a user interface 28 on the user side wall of the first enclosure 20. As is known in the art, the user interface 28 includes a manual switch 29 that can be used to reset the mechanical switching device 22 and reconnect the circuit after the mechanical switching device 22 is actuated to interrupt current flow. The manual switch 29 is typically located on the mechanical circuit breaker module 12, as seen in these drawings. As shown in FIG. 8, the user interface 28 also comprises a push-to-test (PTT) actuator 34 (e.g., button), a communication input device 36 (e.g., button), and a display 38 (e.g., LED (light emitting diode) indicators) for outputting information about the status of the modular MFCB 11 during use. In certain embodiments, the manual switch 29 is part of the mechanical circuit breaker module 12 and the PTT actuator 34, communication device 36, and display 38 are part of the electronics circuit breaker module 14. Not shown is a dedicated controller for the user interface 28, which can comprise a printed circuit board connected to the PTT actuator 34, the communication input device 36, and the display 38 for controlling the various user interface functions of the modular MFCB 11. In one or more embodiments, a wireless communication antenna can be mounted on the user interface printed circuit board for communicating information about the status of the MFCB 11 with an external device (not shown).

The inner end wall of the first enclosure 20 broadly comprises integrated attachment features 30 for attaching the mechanical circuit breaker module 12 to the electronics circuit breaker module 14 to assemble the modular MFCB 11. The same attachment features 30 can also be used in the same way to attach the mechanical circuit breaker module 12 to any of the other electronics circuit breaker modules 14A, 14B, 14C, 14D, 14E depicted in FIG. 1. In the illustrated embodiment, the attachment features 30 comprise yokes configured to make pinned yoke-and-tang couplings with the electronics circuit breaker module 14. More particularly, the attachment features 30 comprise one yoke along the user side wall and another yoke at a location adjacent the equipment side wall. Each yoke 30 comprises a pin opening 32 configured for reception of a pin fastener (e.g., a screw) that fastens the mechanical circuit breaker module 12 to the electronics circuit breaker module 14. It will be understood that other embodiments can facilitate attachment of a mechanical circuit breaker module to an electronics circuit breaker module in other ways without departing from the scope of the disclosure.

The electronics circuit breaker module 14 comprises a second enclosure 40 configured to contain an electronics assembly 42 that includes one or more electronic current sensors 44, 46 configured for detecting current flow through primary conductors 47, 48, 49 that connect the electrical distribution equipment to the load when the MFCB 11 is installed. Suitably, the electronics circuit breaker module 14 is free of mechanical circuit breaker components. In the illustrated embodiment, the conductors 47, 48 are line conductors (e.g., configured to connect to line 1 and line 2 of a 120/240Vrms split phase circuit) and the conductor 49 is a neutral connector.

In the illustrated embodiment, the electronic current sensor 44 is a traditional toroidal differential sensor configured to output a ground fault (GF) signal in response to a differential current in the circuit. Hence, all three conductors 47, 48, 49 pass through the differential sensor 44. The differential sensor 44 can comprise a plurality of discrete windings on one or more cores that perform different functions such as GF detection, grounded-neutral (GN) detection, and PTT stimulation, as described, for example, in US Patent Application Publication No. 2024/0222954, which is assigned to the assignee of the present disclosure.

The electronic current sensor 46 is a printed circuit board (PCB) comprising one or more current transformers (CTs) (e.g., a PCB Rogowski coil) for outputting signals indicating the amount the current flowing through the circuit. Hence, the line conductors 47, 48 (but not the neutral conductor 49) pass through the PCB current sensor 46. The PCB current sensor 46 is configured to output a signal representing the amount of current flowing in the line conductors 47, 48, which can be used by the modular MFCB 11 in various ways such as overcurrent detection, arc fault detection, and energy monitoring.

In the illustrated embodiment, the electronic current sensors 44, 46 are operably connected to an electronics control board 50. The electronics control board 50 (broadly, a controller) comprises one or more microcontrollers configured to receive the signals output by the electronic current sensors 44, 46 and output control signals (e.g., trip signals) that perform protective and/or energy metering functions. For example, the electronics control board 50 can comprise electric metering circuitry and protection circuitry configured to perform electric metering functions and circuit protection functions, respectively. In an example embodiment, the electronics control board 50 is configured to output trip signals (e.g., encoded digital signals for fast tripping) to the solenoid 23 that cause the solenoid to actuate the mechanical switching device 22, e.g., in response any of the following: a GF signal from the differential sensor 44, a GN signal from the differential sensor 44, and/or a current measurement signal from the PCB current sensor 46 indicating an overcurrent condition or an arc fault. In response to the trip signal, the solenoid 23 moves the mechanical switching device 22 to interrupt current flowing through the modular MFCB 11 between the electrical distribution device and the load. For instance, the mechanical switching device 22 is moved to disconnect the current path between the equipment connector 26 and the first electrical module connector 24.

In one or more embodiments, the electronics control board 50 is further configured to transmit to an external device (e.g., via an antenna on the electronics control board or elsewhere) information based on the current measurement signal from the PCB current sensor 46 about the amount of energy being consumed by the circuit. In certain embodiments, the electronics assembly 42 is configured to provide revenue-grade metering of energy consumption by the circuit, and the metering is accurate to within ±0.2%. This is possible, in part, because of the modular design of the modular MFCB 11. By separating the mechanical switching device 22 from the PCB current sensor 46, crosstalk is minimized and accuracy is improved. Further, by separating the mechanical switching device 22 in its own module, it is possible to more accurately route the primary conductors 47, 48, 49 through the (dedicated) electronics circuit breaker module 14, which also enhances the accuracy of the current measurements.

The second enclosure 40 fully contains the electronics assembly 42 such that the electronic current sensors 44, 46 are physically separated from mechanical switching device 22 when the modular MFCB 11 is assembled. Like the first enclosure 20, the second enclosure 40 comprises an inner end wall and an outer end wall spaced apart along the first axis A1, a first broad side wall and a second broad side wall spaced apart along the second A2, and an equipment side wall and a user side wall spaced apart along a third axis A3. Load connectors 52 (e.g., pigtail terminals) are located on the outer end wall for connecting the modular MFCB 11 to conductors of a building circuit that run from the modular MFCB to the load.

A second electrical module connector 54 is on (e.g., exposed on) the inner end wall of the second enclosure 40. The second electrical module connector 54 is configured to make an electrical connection to the first electrical module connector 24 when the electronics circuit breaker module 14 is attached to the first mechanical circuit breaker module 12 (e.g., in the illustrated example, the second electrical module connector 54 is a spring clip contact, the first electrical module connector 24 is a flat strip contact, and the second electrical module connector 54 is configured to clip onto the first electrical module connector when the mechanical circuit breaker module 12 and electronics circuit breaker module 14 are attached). At least one primary conductor 47, 48 of the electronics circuit breaker module 14 connects the second electrical module connector 54 to a load connector 52. Hence, when the mechanical circuit breaker module 12 is attached to the electronics circuit breaker module 14, a (selectively interruptible) current pathway is established between the equipment connector 26, the first electrical module connector 24, the second electrical module connector 54, the primary conductor(s) 47, 48, and the respective load connector(s) 52. During use, current flowing through the modular MFCB 11 between the electrical distribution equipment and the load flows on this pathway. This enables the current sensors 44, 46 to sense faults and/or measure current flowing on the primary conductors 47, 48 and output corresponding signals to a controller implemented on the control board 50. In turn, the controller is configured to selectively issue trip signals to the solenoid 23 that cause the solenoid to actuate the mechanical switching device 22 to interrupt current flow on the pathway.

The mechanical circuit breaker module further comprises another equipment connector 56 exposed on the equipment side wall of the second enclosure 40. The equipment connector 56 is suitably configured to connect to a neutral conductor in electrical distribution equipment (not shown). The primary conductor 49 extends through the differential current sensor 44 and connects the equipment connector 49 to a load connector 52.

The second enclosure 40 broadly comprises integrated attachment features 60 for attaching the electronics circuit breaker module 14 to the mechanical circuit breaker module 12 to assemble the modular MFCB 11. In the illustrated embodiment, the attachment features 60 comprise tangs configured to make pinned yoke-and-tang couplings with the yokes 30 on the first enclosure 20. More particularly, there is one tang 60 along the user side wall for reception in the corresponding yoke 30 of the first enclosure 20 and another tang (not shown) along the inner end wall for reception in the other yoke of the first enclosure. Each tang 60 comprises a pin opening 62 configured to align with the pin openings 32 of the corresponding yoke so that a pin may be inserted into the aligned pin openings to attach the tang to the yoke and thereby attach the first enclosure to the second enclosure via a pinned yoke-and-tang coupling.

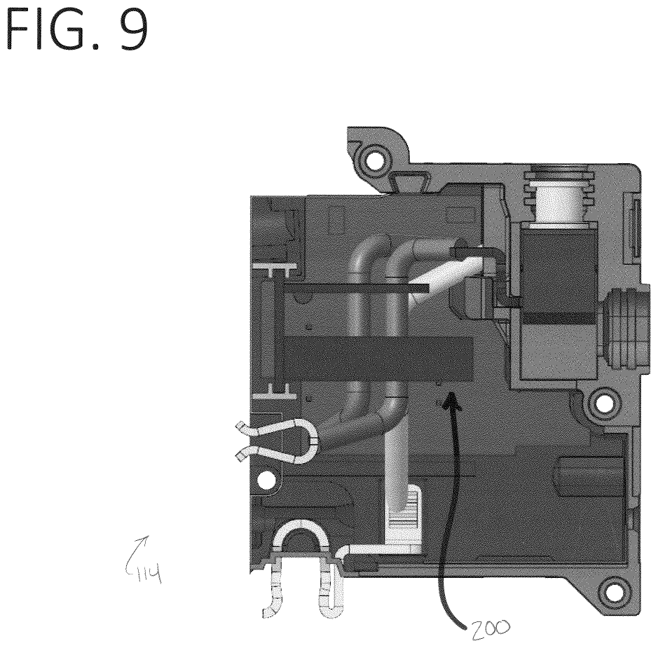

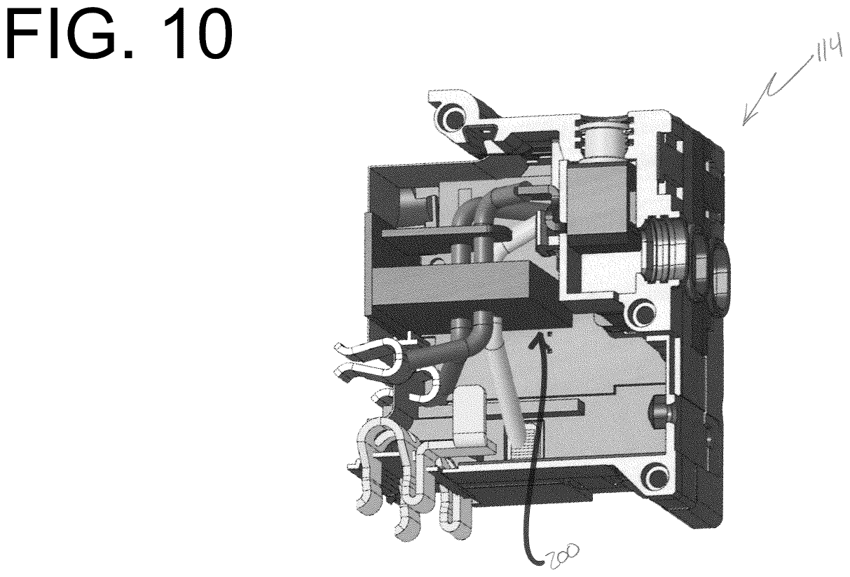

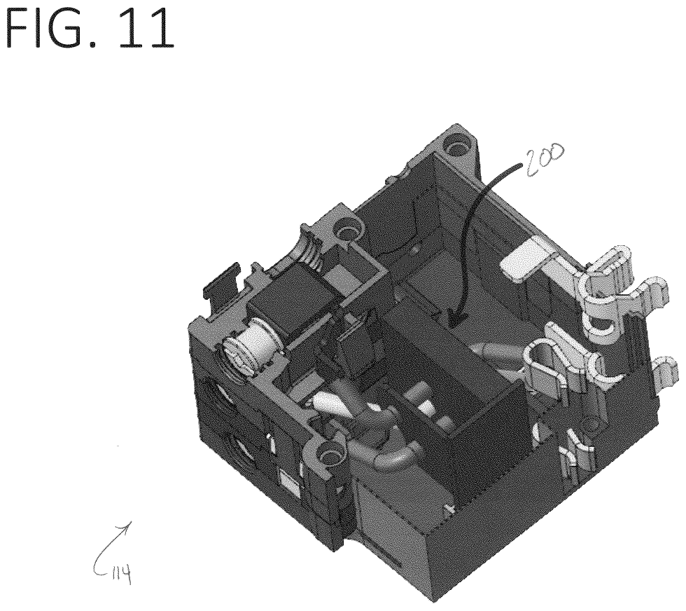

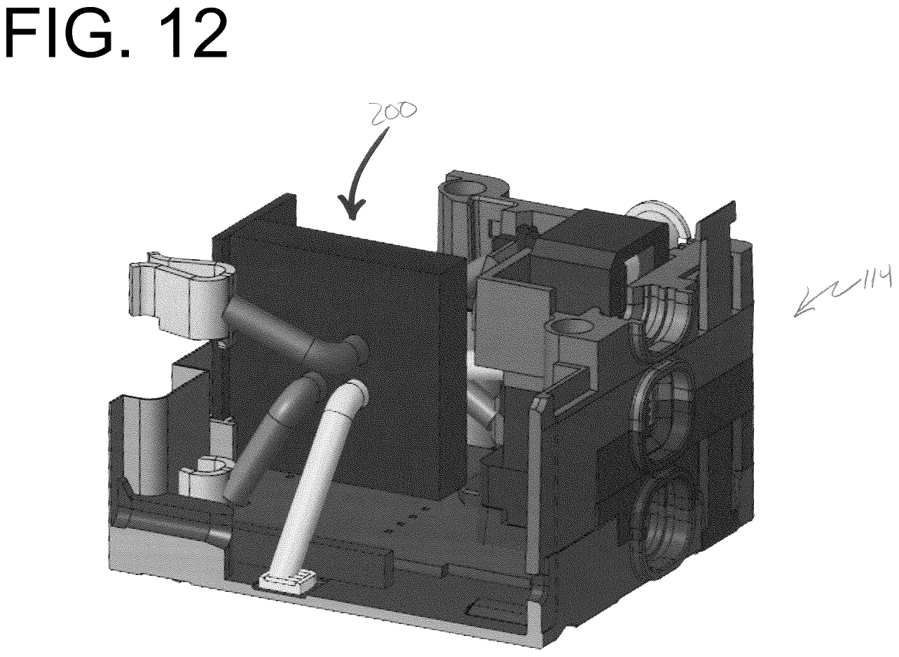

Referring to FIGS. 9-13, another example embodiment of an electronics circuit breaker module for a modular MFCB is generally indicted at reference number 114. The electronics circuit breaker module 114 is similar to the electronics circuit breaker module 14, and like the previously described electronics circuit breaker module, is configured to operatively connect to the mechanical circuit breaker module 12 to make a complete modular MFCB. The electronics circuit breaker module 114 is essentially the same in all respects to the electronics circuit breaker module 14 except that the traditional loop-shaped differential sensor 44 is replaced by a new printed circuit board assembly (PCBA) differential sensor system 200, which will be described in detail below.

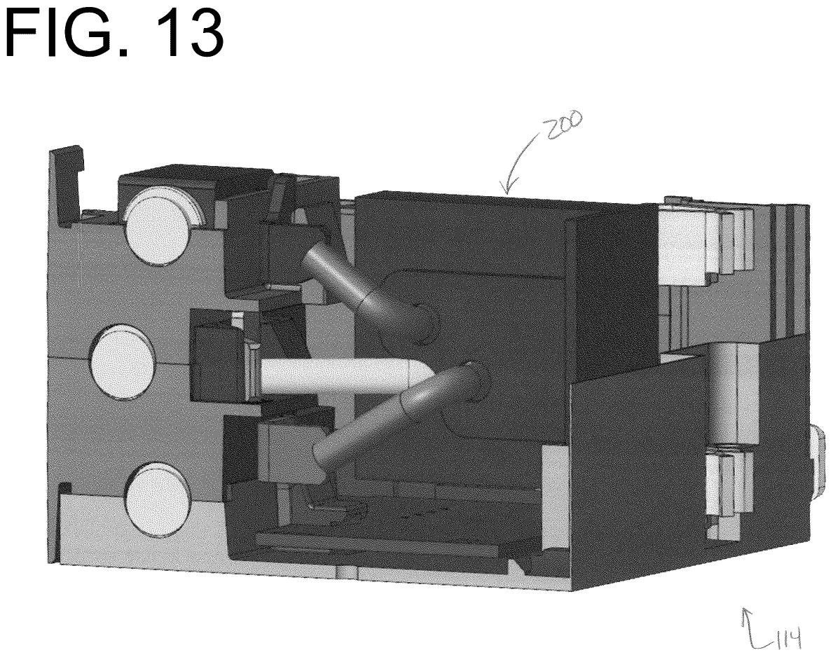

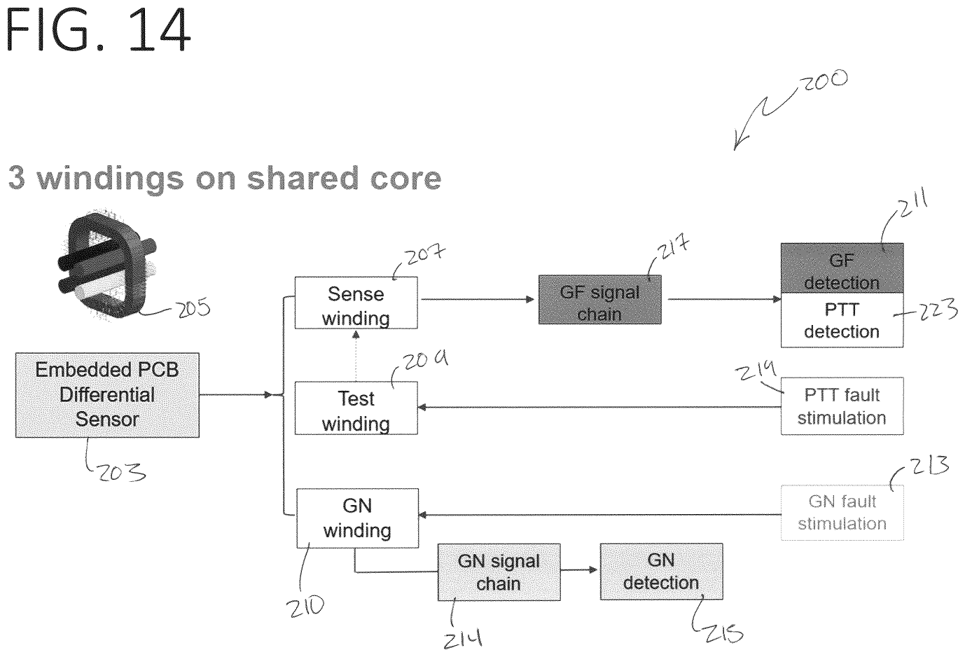

Referring to FIG. 14, in an example embodiment, the PCBA differential sensor system 200 comprises a multifunction current transformer 203 integrated into a PCBA. The way the current transformer 203 is constructed on a PCBA will be described in greater detail below, but first this disclosure provides a brief overview of example functions that can be performed by the multifunction current transformer 203.

In one embodiment, the PCBA sensor system 200 comprises similar multifunctional capabilities to the multifunction differential sensor system described in US Patent Application Publication No. 2024/0222954, which is assigned to the assignee of the present disclosure. The PCBA sensor system 200 is broadly configured to provide comprehensive fault detection by integrating multiple functions in a single current transformer 203 on a PCBA. As shown schematically, the single, integrated current transformer 203 comprises a loop-shaped core 205 with a sense winding 207, a test winding 209, and a grounded neutral (GN) winding 210 wound around the core 205. The way the core 205 and the windings 207, 209, 210 are integrated into the PCBA will be described in further detail below.

The sense winding 207 is generally configured for detecting ground faults. In the illustrated embodiment, the sense winding 207 is operatively connected to a GF signal chain 217 that processes signals from the sense winding and feeds them into a GF detector 211. The GF detector 211 is responsible for identifying line-to-ground fault conditions. The GF detector 211 also incorporates a PTT detection functionality, as illustrated by the PTT detector 223.

The test winding 209 is operatively connected to a PTT signal stimulator 219. The primary role of the PTT signal stimulator 219 is to, upon activation (e.g., by a manual PTT button or an automated self-test command), output a test signal to the test winding 209. This test signal simulates a GF condition by creating a magnetic flux imbalance in the core 205. The test signal, which can have identifiable characteristics such as a specific amplitude, frequency, or waveform (e.g., a square wave signal), is electromagnetically coupled from the test winding 209 to the sense winding 207 via their shared magnetic link to the core 205. This coupling induces a corresponding signal in the sense winding 207, mimicking the signal that would be present during a GF condition. This induced signal from the sense winding 207 is subsequently processed by the GF signal chain 217 and detected by the PTT detector 223 (which may be integrated with or distinct from the GF detector 211). The successful detection of this specific test signal by the PTT detector 223 serves to verify the operational integrity of the components in the GF pathway.

The GN winding 210 is operatively connected to a GN stimulator 213 and a GN detector 215 (via a GN signal chain 214). The GN stimulator 213 provides a signal to the GN winding 210, and the GN detector 215 monitors signals from this winding to determine if a GN fault condition exists. In this configuration, the GN detection pathway is distinct and operates using its own dedicated winding, stimulus, and detector.

The various detectors (e.g., GF detector 211, PTT detector 223, GN detector 215) and stimulators (e.g., PTT signal stimulator 219, GN stimulators 213) described herein may be realized through any suitable hardware or software-implemented configuration. For example, a microcontroller unit (MCU) can execute firmware to perform signal processing, logic operations, and waveform generation. The MCU typically interfaces with analog front-end (AFE) circuitry that conducts signal conditioning. This AFE circuitry can include operational amplifiers for signal amplification, comparators for threshold detection, and filters (comprising resistors, capacitors, and inductors) to remove noise and select desired signal components from the sense windings before digitization by the MCU's analog-to-digital converters (ADCs). For stimulus generation, the MCU may utilize digital-to-analog converters (DACs), pulse width modulation (PWM) outputs, or general-purpose input/output (GPIO) pins, potentially in conjunction with driver circuits (such as transistors or dedicated driver ICs) to provide sufficient power to the respective stimulus windings. In alternative embodiments, some or all of the functionalities of these modules may be implemented using application-specific integrated circuits (ASICs), which can consolidate many of the analog and digital functions into a single integrated circuit, or through discrete logic components and dedicated ICs.

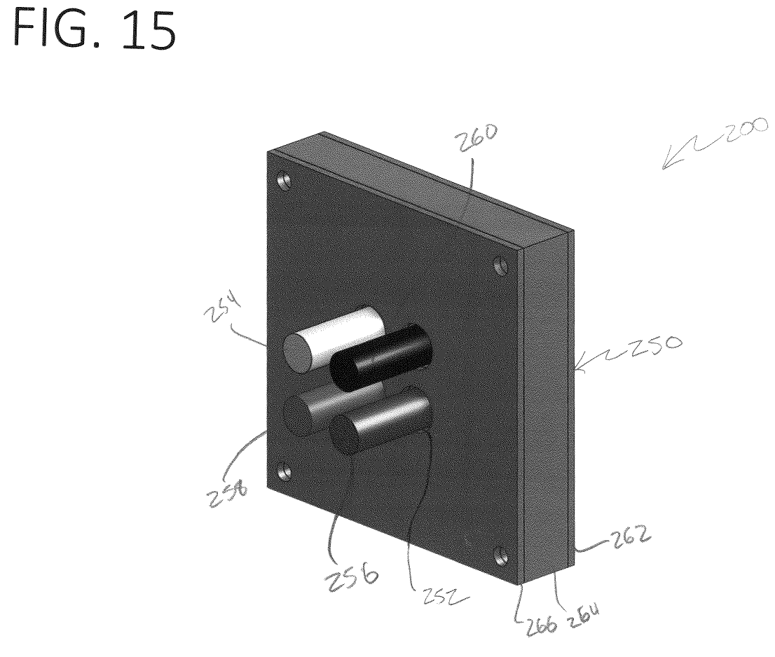

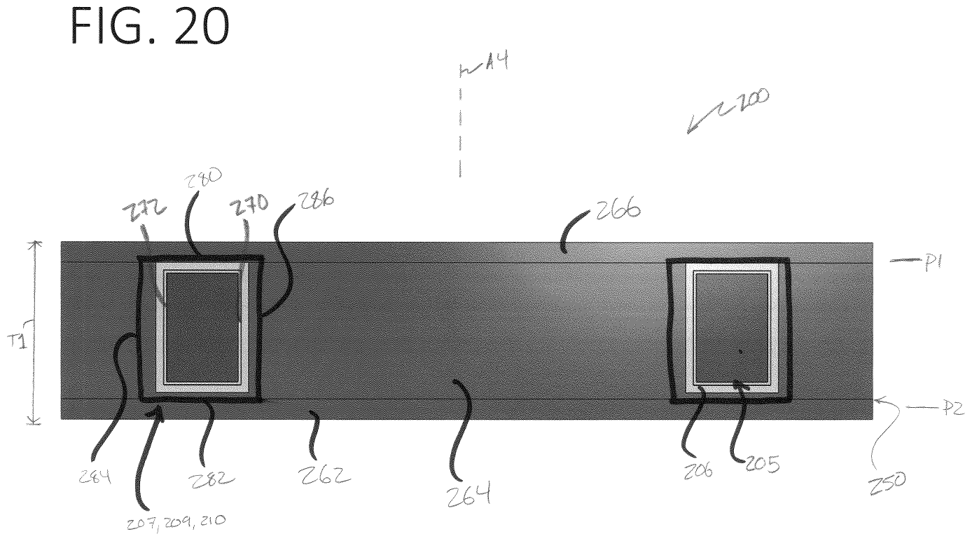

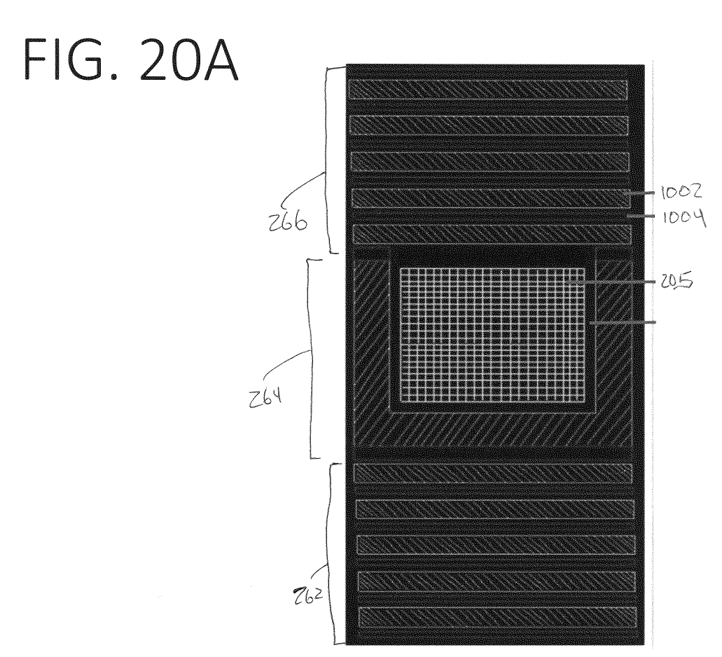

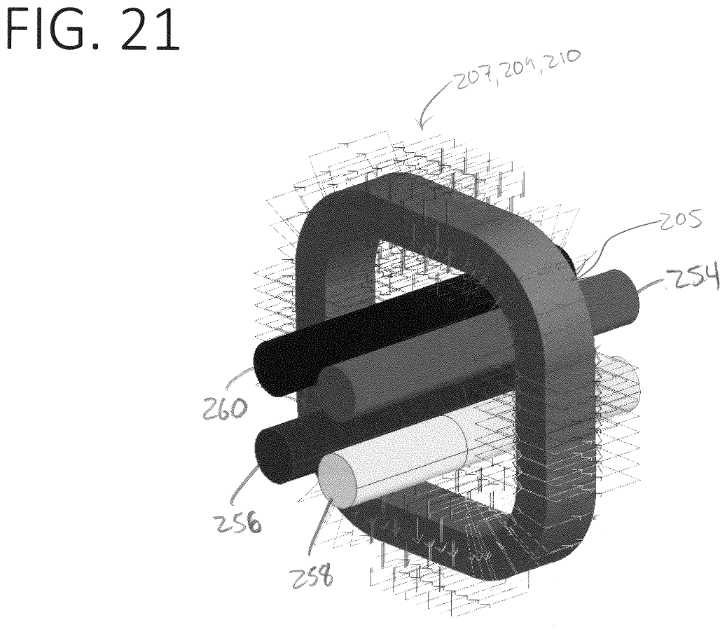

Referring now to FIGS. 15-23, the PCBA structure of the PCBA differential sensor system 200 will now be described in further detail. The PCBA differential sensor system 200 broadly comprises a PCBA substrate 250 (e.g., a dielectric substrate) having a thickness T1 (FIG. 20) along an axis A4. Along the thickness T1, the substrate 250 comprises a bottom region 262, a middle region 264, and a top region 266. Each region 262, 264, 266 may, itself, be composed from one or more PCB layers. In one example depicted in FIG. 20A, the middle region 264 is dielectric material, and each of the bottom region 262 and the top region 266 is a stack of five dielectric PCB layers 1002 with alternating conductive PCB layers 1004 in between to form portions of the windings 207, 209, 210. As explained below, the middle region 264 is configured to receive the CT core 205. The bottom region 262 is below the middle region 264, and the top region 266 is above the middle region 264. The regions 262, 264, 266 may be formed separately and fastened together, or alternatively, two or more substrate regions could comprise one monolithic piece of material. The PCBA substrate 250 defines at least one conductor opening 252 extending along the axis A4 through the entire thickness T1 such that a plurality of primary conductors 254, 256, 258, 260 can pass through the PCBA a central portion of the substrate. In the illustrated embodiment, the PCBA substrate 250 defines four spaced apart conductor openings 252, one for each individual primary conductor 254, 256, 258, 260. Each conductor opening 252 is configured to hold a respective one of the conductors 254, 256, 258, 260 at defined position so that the conductors have a symmetrical arrangement in the core 205.

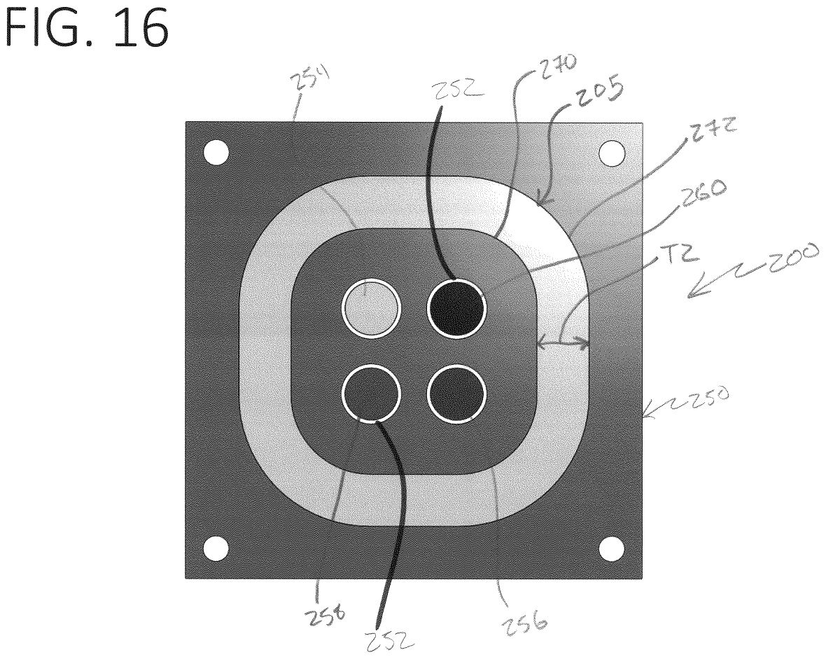

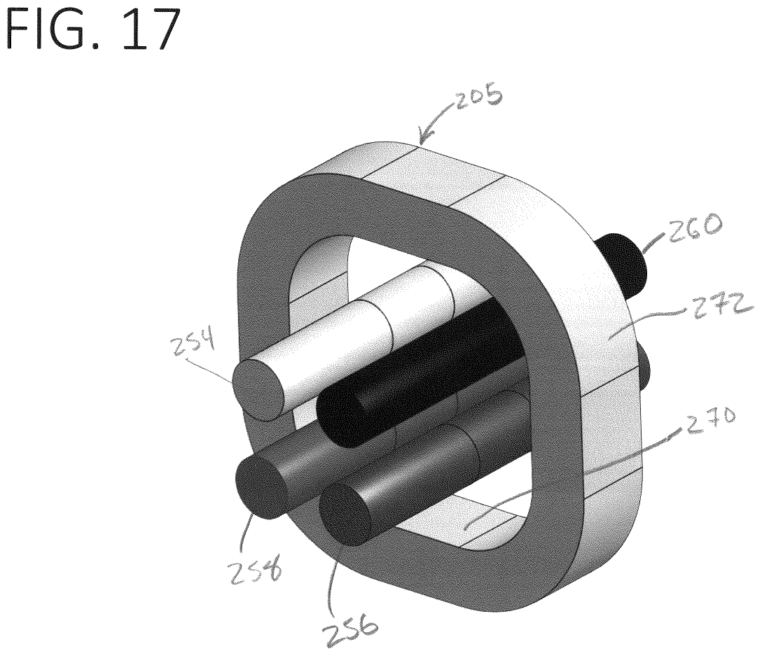

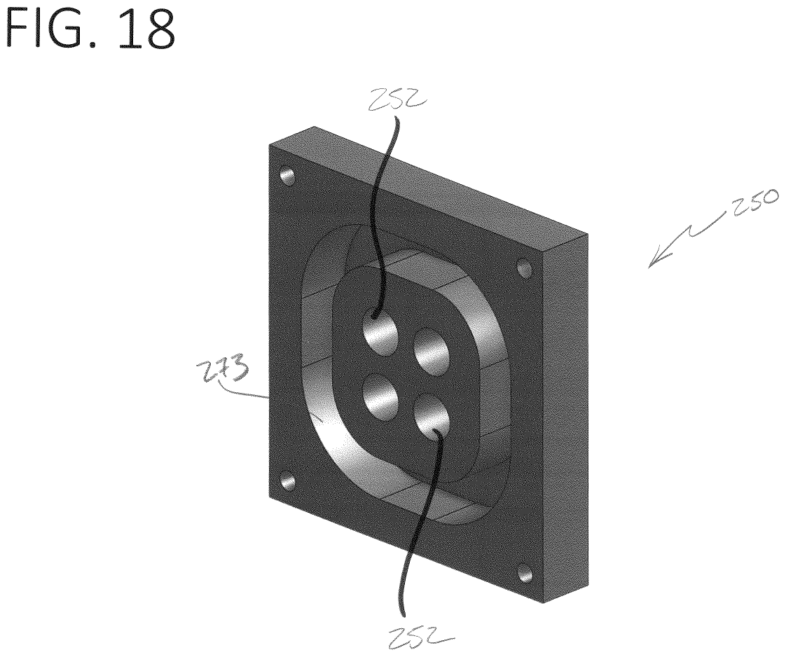

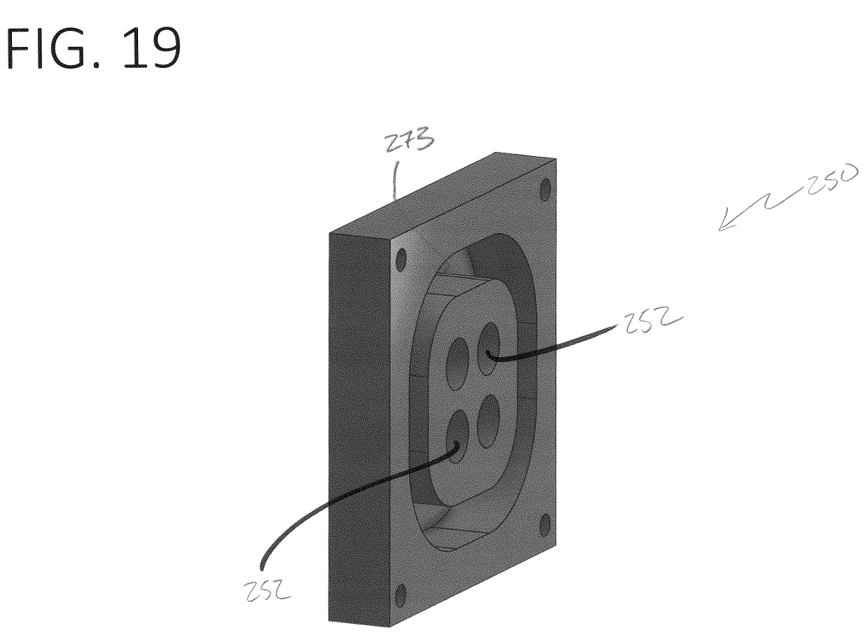

The CT core 205 has a loop shape (e.g., a polygonal loop shape) and is embedded in the PCBA substrate 250 so as to circumscribe the conductor openings 252. The CT core 205 defines a closed loop and has an inner perimeter side 270, an outer perimeter side 272, and a radial thickness T2 (FIG. 16) extending from the inner perimeter side to the outer perimeter side. In the illustrated embodiment, the perimeter shape of the CT core 205 is that of a square with rounded corners. The CT core could also have other perimeter shapes without departing from the scope of the disclosure. Suitably the CT core 205 is formed from ferromagnetic and/or nanocrystalline material (e.g., with high permeability and high saturation flux density for proficient magnetic flux capture) and is coated with an epoxy layer 206 (FIG. 20). As shown in FIGS. 18-19, the PCBA substrate 250 (e.g., the middle region 264 of the substrate) comprises a loop-shaped receptacle 273 circumscribing the conductor openings 252 and configured to receive the CT core 205 therein (e.g., the CT core can have a close tolerance fit with the PCBA substrate 250 when received in the loop-shaped receptacle 273).

In the illustrated example, the conductor 254 is a first line conductor configured to connect to a first line conductor (e.g., Line 1 conductor) of a circuit, the conductor 256 is a second line conductor configured to connect to a second line current conductor (e.g., Line 2 conductor) of a circuit, the conductor 258 is a neutral conductor configured to connect to a neutral conductor of a circuit, and the conductor 260 is a ground conductor configured to connect to a ground conductor of a circuit. As shown in FIG. 16, in plan, the four conductor openings 252 are centered on the four corners of an imaginary square that is centered on the center of the CT core 205 and (loop-shaped receptacle 273), and the sides of the imaginary square are parallel to the sides of the CT core. Thus, in the illustrated example, the current carrying conductors 254, 256, 258 are arranged in an L-shape at three corners of the imaginary square, with the two line current conductors arranged on the diagonal of the imaginary square.

Referring to FIG. 20, the way the PCBA conductors are formed on the substrate 250 to define the windings 207, 209, 210 will now be described. As shown, each winding 207, 209, 210 is formed from upper winding traces 280 on the top region 266, lower winding traces 282 on the bottom region 262, and winding via barrels 284, 286 formed through the middle region 264. Each winding via barrel 284, 286 comprises conductive plating on a via of the substrate 250. Each upper winding trace 280 extends in a plane P1 of the top region 266, and each lower winding trace 282 extends in a plane P2 of the bottom region 262. The planes P1 and P2 are parallel to one another and orthogonal to the axis A4. The via barrels 284, 286 extend generally parallel to the axis A4 at spaced apart locations.

Each winding via barrel 284, 286 connects one upper winding trace 280 to one lower winding trace 282. Each upper winding trace 280 extends from an upper outboard end portion outboard of the outer perimeter side 272 of the CT core 205 to an upper inboard end portion inboard of the inner perimeter side 270 of the CT core. Each lower winding trace 282 extends from a lower outboard end portion outboard of the outer perimeter side 272 of the CT core 205 to a lower inboard end portion inboard of the inner perimeter side 270 of the CT core. Outboard winding via barrels 284 each connect the upper outboard end portion of one upper winding trace 280 to the lower outboard end portion of one lower winding trace 282. Inboard winding via barrels 286 each connect the upper inboard end portion of one upper winding trace 280 to the lower inboard end portion of one lower winding trace 282. For each winding 207, 209, 210, the upper winding traces 280, the lower winding traces 282, the outboard via barrels 284, and the inboard via barrels 286 are arranged on the PCBA substrate 250 to form a continuous winding that winds around the CT core 205 at least n consecutive times.

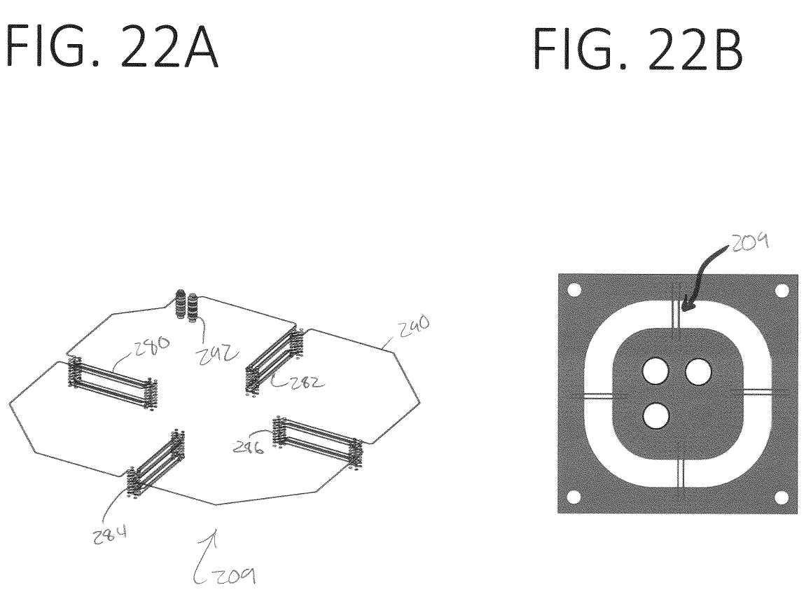

Referring to FIGS. 22A-22B, an example embodiment of the layout of a set of PCBA conductors 280, 282, 284, 286 forming a test winding 209 is shown. In this example, the winding 209 winds around each side of the four-sided CT core 205 two consecutive times. Connecting traces 290 formed on the top substrate region 266 (in the plane P1) connect the windings on each of the four sides of the core 205 to terminal vias 292. The terminal vias 292, in turn, connect the test winding 209 to the PTT signal stimulator 219 described above.

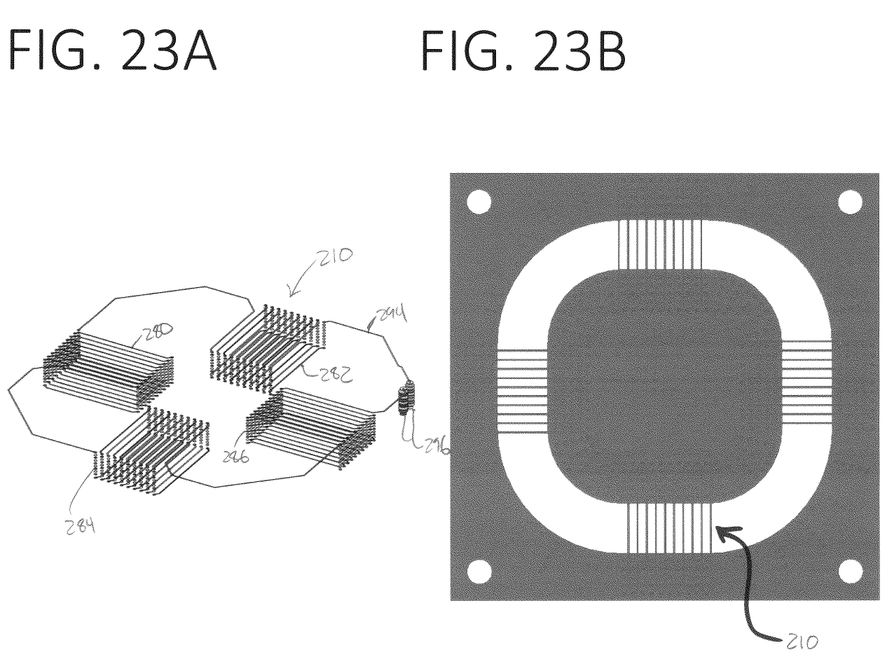

Referring to FIGS. 23A-23B, an example embodiment of the layout of a set of PCBA conductors 280, 282, 284, 286 forming a GN winding 210 is shown. In this example, the GN winding 210 winds around each side of the four-sided CT core 205 ten consecutive times. Connecting traces 294 formed on the top substrate region 266 (in the plane P1) connect the windings on each of the four sides of the core 205 to terminal vias 296. The terminal vias 296, in turn, connect the GN winding 210 to the GN stimulator 213 and GN detector 215 described above.

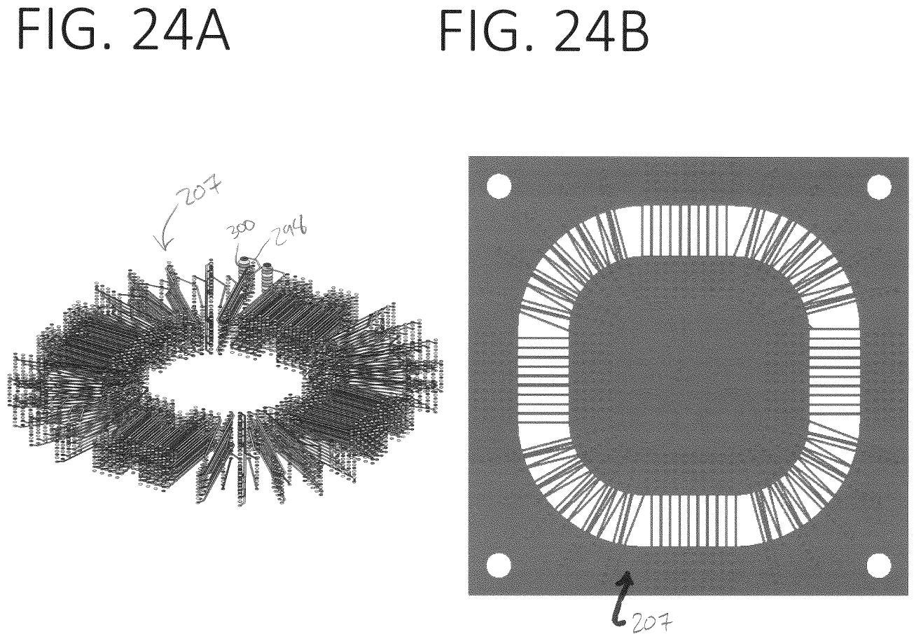

Referring to FIGS. 24A-24B, an example embodiment of the layout of a set of PCBA conductors 280, 282, 284, 286 forming a sense winding 207 is shown. In this example, the sense winding 207 winds around each side of the four-sided CT core 205 ten consecutive times and winds around each rounded corner of the CT core 205 ten consecutive times (which again, the specific number of turns the winding takes is shown for purposes of example only and will vary depending on the application). Connecting traces 298 formed on the top substrate region 266 (in the plane P1) connect the windings on each of the four sides and each of the four corners of the core 205 to terminal vias 300. The terminal vias 300, in turn, connect the sense winding 207 to the GF signal chain 217 and the GF detector 211 as described above.

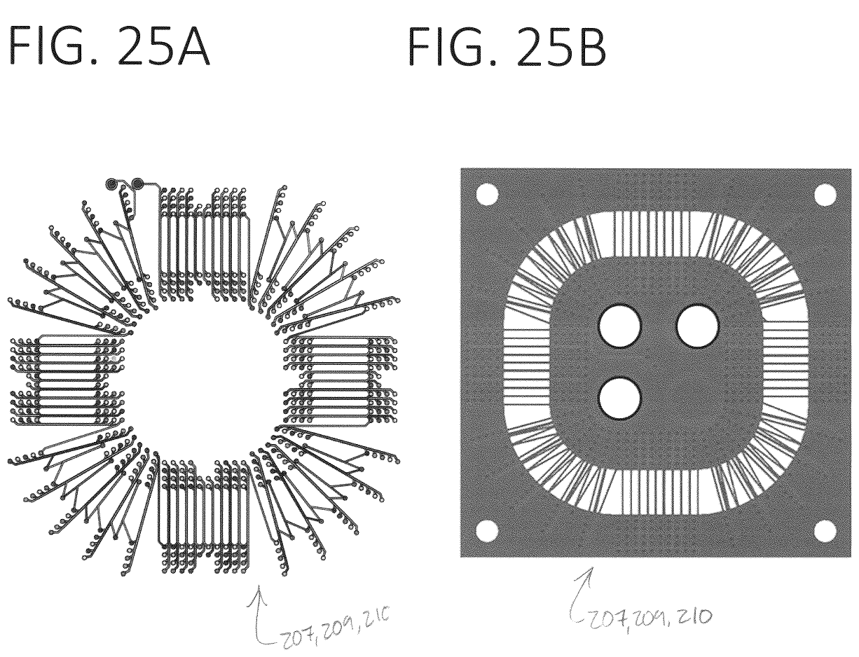

FIGS. 25A-25B depict the superimposed layout of the three windings 207, 209, 210.

Accordingly, it can be seen that the PCBA differential sensor system 200 enables a differential current transformer to be constructed using high-precision PCBA manufacturing techniques. This allows for very accurate control of winding pitch and distribution, which heretofore has not been achievable using a closed core CT. Furthermore, by forming conductor openings 252 directly in the PCBA substrate using high precision PCBA manufacturing processes, it is also possible to precisely control the position of the primary conductors 254, 256, 258, 260 as they pass through the closed core. Precise control over these physical parameters can directly impact the current sensor's electromagnetic characteristics and performance detecting ground faults, grounded neutral conditions and test stimuli.

The pitch and distribution of each winding 207, 209, 210 around the loop-shaped core 205 determine how uniformly it couples with the magnetic flux generated by the primary current-carrying conductors 254, 256, 258, 260 and with other windings. Precise control of the winding geometry ensures that the induced voltage in the sense winding 207 accurately reflects the differential current (for GF detection) or the specific stimulus (for PTT or GN detection). Deviations from the designed winding pitch and distribution (which are common in conventional closed core CT manufacturing) can, by contrast, lead to variations in sensitivity, incorrect readings, or an inability to detect subtle fault conditions. The precise manufacturing control unlocked by incorporating the closed core CT into a PCBA using PCBA manufacturing techniques ensures that variations in winding placement or conductor paths do not lead to unit-to-unit performance discrepancies. This reduces the need for extensive individual calibration, lowers manufacturing costs, and ensures devices meet safety and operational standards consistently.

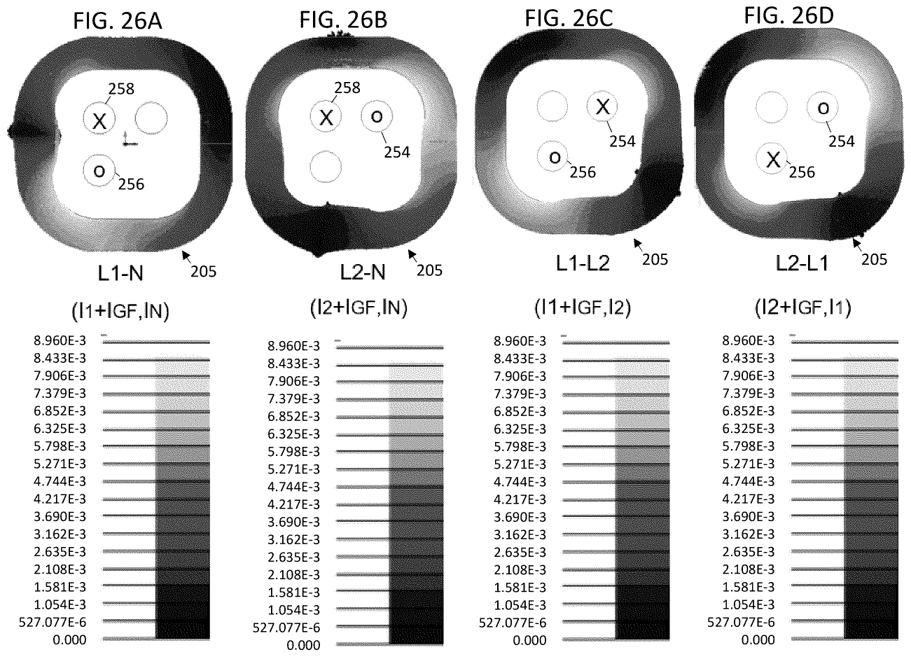

FIGS. 26A-26D show the electromagnetic flux response to four ground fault scenarios that can occur in the PCBA differential sensor system 200. Because the winding pitch and winding distribution are accurately controlled, it is possible to achieve a highly predictable and consistent electromagnetic flux response across these varied scenarios. This precise control allows for a clearer distinction between actual fault signatures and background noise or benign system transients, leading to more reliable fault detection, a significant reduction in the probability of false positives or negatives, and an overall improvement in the sensor's capabilities.

When introducing elements of the present disclosure or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the disclosure are achieved and other advantageous results attained.

As various changes could be made in the above products and methods without departing from the scope of the disclosure, it is intended that all matter contained in the above description shall be interpreted as illustrative and not in a limiting sense.

What is claimed is:

1. A printed circuit board assembly (PCBA) differential sensor system for use in a circuit breaker, the PCBA differential sensor system comprising:
a PCBA substrate defining a conductor opening, the conductor opening configured to receive a primary conductor;
a current transformer (CT) core in the PCBA substrate and circumscribing the conductor opening; and
PCBA conductors on the PCBA substrate to define at least one winding around the CT core.

2. The PCBA differential sensor system of claim 1, wherein the PCBA substrate comprises a middle region defining a loop-shaped receptacle, the CT core received in the loop-shaped receptacle.

3. The PCBA differential sensor system of claim 2, wherein the PCBA substrate further comprises a bottom region under the CT core and a top region over the CT core.

4. The PCBA differential sensor system of claim 3, wherein the PCBA conductors include upper winding traces on the top region, lower winding traces on the bottom region, and winding via barrels in the middle region, each winding via barrel connecting one upper winding trace to one lower winding trace.

5. The PCBA differential sensor system of claim 4, wherein the winding via barrels comprise inboard winding via barrels on an inboard side of the CT core and outboard winding via barrels on an outboard side of the CT core.

6. The PCBA differential sensor system of claim 4, wherein the conductor opening comprises a first conductor opening configured to receive a first line conductor, a second conductor opening configured to receive a second line conductor, and a third conductor opening configured to receive a neutral conductor.

7. The PCBA differential sensor system of claim 1, wherein the PCBA conductors comprise a first set of PCBA conductors on the PCBA substrate to define a ground fault (GF) sense winding around the CT core.

8. The PCBA differential sensor system of claim 7, wherein the PCBA conductors further comprise a second set of PCBA conductors on the PCBA substrate to define a test winding around the CT core.

9. The PCBA differential sensor system of claim 8, wherein the PCBA conductors further comprise a third set of PCBA conductors on the PCBA substrate to define a grounded neutral (GN) winding around the CT core.

10. The PCBA differential sensor system of claim 9, further comprising a GN stimulator connected to the GN winding and configured to output a GN fault stimulus signal to the GN winding and a GN detector connected to the GN winding and configured to receive signals output by the GN winding in response to the GN fault stimulus signal, the GN detector configured to detect a GN fault based on the signals output by the GN winding in response to the GN fault stimulus signal.

11. The PCBA differential sensor system of claim 8, further comprising a GF detector connected to the GF winding and configured to receive signals from the GF winding and detect ground faults based on the signals received from the GF winding.

12. The PCBA differential sensor system of claim 11, further comprising a test signal stimulator operatively connected to the test winding and configured to output a test stimulus signal to the test winding.

13. The PCBA differential sensor system of claim 12, wherein the GF winding is configured to output a response signal in response to the test stimulus output to the test winding and wherein the GF detector is configured to detect the response signal, and in response, to output a control signal to a switching device of the circuit breaker.

14. A modular multifunction circuit breaker (MFCB) comprising:
a mechanical circuit breaker module comprising a first enclosure, a first electrical module connector on the first enclosure, and a mechanical switching device in the enclosure and configured to be selectively actuated to interrupt current flow between electrical distribution equipment and a load; and
an electronics circuit breaker module comprising a second enclosure, a second electrical module connector on the second enclosure, an electronic current sensor in the second enclosure, and a controller connected to the electronic current sensor;
wherein the electronics circuit breaker module is attachable to the mechanical circuit breaker module, wherein when the electronics circuit breaker module is attached to the mechanical circuit breaker module, an electrical connection is made between the second electrical module connector and the first electrical module connector such that the electronic current sensor is configured to sense current flowing through the modular MFCB between the electrical distribution equipment and the load and the controller is configured, based on the sensed current, to issue trip signals configured to actuate the mechanical switching device based on the sensed current.

15. The modular MFCB of claim 14, wherein the electronics circuit breaker module further comprises electric metering circuitry in the second enclosure.

16. The modular MFCB of claim 15, wherein the modular MFCB is configured to provide revenue-grade metering with ±2% accuracy.

17. The modular MFCB of claim 14, wherein the electronic current sensor is a PCBA differential sensor system.

18. The modular MFCB of claim 14, wherein the first enclosure and the second enclosure are configured to attach via a pinned yoke-and-tang coupling.

19. The modular MFCB of claim 14, wherein the electronic current sensor is a loop-shaped differential sensor.

20. A mechanical circuit breaker module comprising:
an enclosure;
a mechanical switching device in the enclosure and configured to be selectively actuated to interrupt current flow between electrical distribution equipment and a load;
an equipment connector configured to connect to the electrical distribution equipment; and
an electrical module connector;
wherein the enclosure is configured to attach to any one electronics circuit breaker module selected from a set of electronics circuit breaker modules of a plurality of different electronics circuit breaker module types whereby an electrical connection is made between the module electrical connector and a module electrical connector of the selected electronic circuit breaker module configured to connect a primary conductor of a current sensor of the electronics circuit breaker module to the electrical equipment connector.
